(19) United States
(12) Patent Application Publication
(10) Pub. No.: US 2012/0125407 A1
(43) Pub. Date: May 24, 2012

(54) SOLAR MODULE

(75) Inventor: Hsuan-Ping CHEN, Kaohsiung County (TW)

(73) Assignee: DU PONT APOLLO LIMITED, Hong Kong (HK)

(21) Appl. No.: 12/949,749

(22) Filed: Nov. 18, 2010

(51) Int. Cl. H01L 31/05

(52) U.S. Cl. 136/251

(57) ABSTRACT

A solar module is disclosed, which includes a solar cell panel, a back plate disposed on the solar cell panel and having a hole, a junction box disposed on the back plate, plural metallic wires passing through the hole for connecting the solar cell panel and the junction box, and a moisture absorbent disposed between the junction box and the solar cell panel to absorb the moisture around the hole.

### BACKGROUND

1. Field of Invention

The present invention relates to a solar module. More particularly, the present invention relates to a sealing structure of the solar module.

2. Description of Related Art

The increasing scarcity and the realization of the ecological and safety problems associated with non-renewable energy resources such as coal, petroleum and uranium, have made it essential that increased use be made of alternate non-depletable energy resources such as solar energy. Solar energy use has been limited in the past to special applications due in part to the high cost of manufacturing devices capable of producing significant amounts of photovoltaic energy. The improvement in manufacturing technology for fabricating the solar panel in mass production has greatly promoted the use of solar energy.

Significant environmental benefits are also realized from solar energy production, for example, reduction in air pollution from burning fossil fuels, reduction in water and land use from power generation plants, and reduction in the storage of waste byproducts. Solar energy produces no noise, and has few moving components.

The solar module mainly includes a solar cell, a back plate, a frame for fixing the solar cell and the back plate within. The solar cell is further connected to a junction box via the metallic wires. However, the metallic metallic wires of the solar module around the hole would rust easily and reduce the efficiency of the solar module. Therefore, there is a need to prevent the metallic wires of the solar cell around the hole from rusting.

### SUMMARY

An object of the invention is to provide a solar module having a moisture absorbent to prevent the metallic wires of the solar cell from rusting.

An aspect of the invention is a solar module. The solar module includes a solar cell panel having plural solar cells, a back plate having a hole and disposed on the solar cell panel, a junction box disposed on the back plate, plural metallic wires passing through the hole for connecting the solar cell panel and the junction box, and a moisture absorbent disposed between the junction box and the solar cell. The solar module further includes an encapsulant material for adhering the back plate to the solar cell. The solar module further includes a potting material disposed in the junction box. The solar module further includes a sealant disposed between the junction box and the back plate for sealing the hole. The solar module may optionally include a moisture-absorb material. The moisture-absorb material can be blended with the encapsulant material, the potting material or the sealant. The material of the moisture absorbent is selected from a group consisting of zeolite, barium oxide, calcium oxide, and the combination thereof. The moisture absorbent is a sheet.

Another aspect of the invention is a solar module. The solar module includes a solar cell panel having plural solar cells, a back plate having a hole and disposed on the solar cell panel, a junction box disposed on the back plate, plural metallic wires passing through the hole for connecting the solar cell panel and the junction box, and a moisture absorbent disposed adjacent to the hole. The solar module further includes an encapsulant material for adhering the back plate to the solar cell. The solar module further includes a potting material disposed in the junction box. The solar module further includes a sealant disposed between the junction box and the back plate for sealing the hole. The solar module may optionally include a moisture-absorb material. The moisture-absorb material can be blended with the encapsulant material, the potting material or the sealant. The material of the moisture absorbent is selected from a group consisting of zeolite, barium oxide, calcium oxide, and the combination thereof. The moisture absorbent is a sheet.

The solar module of the present invention has the moisture absorbent disposed between the junction box and the solar cell to absorb the moisture around the hole of the back plate. Thus, the metallic wires of the solar cell around the hole would not rust easily. The solar module may optionally include the moisture-absorb material. The moisture-absorb material can be blended with the encapsulant material, the potting material or the sealant.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross section diagram of a first embodiment of the solar cell of the invention;

FIG. 2 is a cross section diagram of a second embodiment of the solar cell of the invention;

FIG. 3 is a cross section diagram of a third embodiment of the solar cell of the invention; and

FIG. 4 is a cross section diagram of a fourth embodiment of the solar cell of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

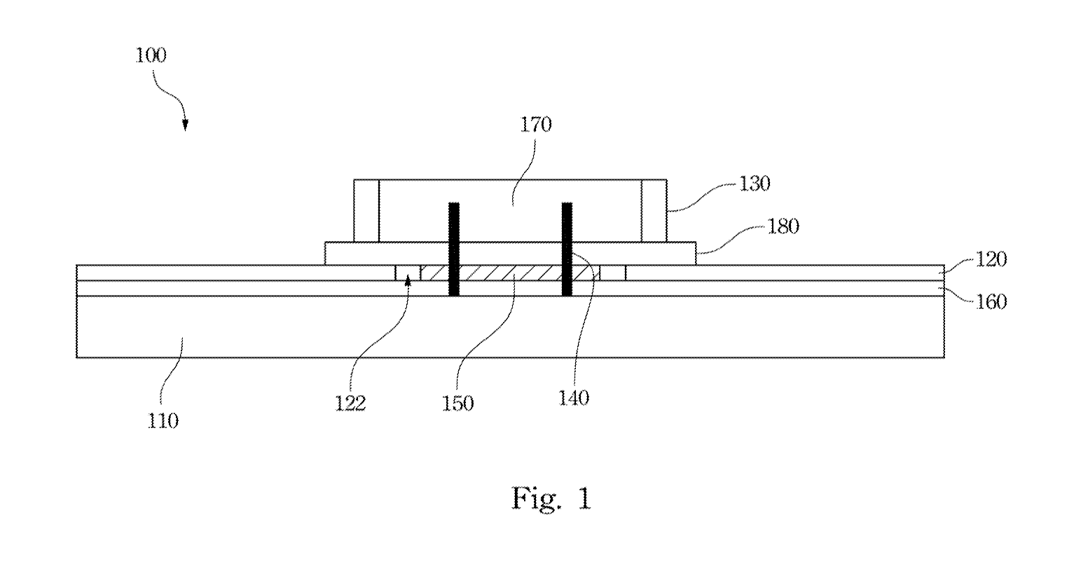

Refer to FIG. 1. FIG. 1 is a cross section diagram of a first embodiment of the solar module of the invention. The solar module 100 includes a solar cell panel 110, a back plate 120 having a hole 122, a junction box 130, plural metallic wires 140 for electrically connecting the junction box 130 and the solar cell of the solar cell panel 110. The metallic wires 140 pass through the hole of the back plate 120 to electrically connect the solar cell panel 110 and the junction box 130.

The solar module 100 further includes an encapsulant material 160 to encapsulate the back plate 120 and the solar cell panel 110. The material of the encapsulant material 160 can be EVA (ethylene vinyl acetate), which may react to the moisture and then produce an acetic acid to damage the solar cell of the solar cell panel 110 and the metallic wires 140 thereof. The efficiency of the solar module 100 would be thus degraded due to the reaction of the moisture and the encapsulant material 160.

The solar module 100 further includes a moisture absorbent 150. The moisture absorbent 150 is disposed between the solar cell panel 110 and the junction box 130 to absorb the moisture, and the reaction of the moisture and the encapsulant material 160 can be prevented. The moisture absorbent 150 is disposed in the hole 122 in this embodiment.

One of the function of the back plate 120 in the solar module 100 is to keep the moisture away from the solar cell panel 110. However, the moisture might enter the inside of the solar cell panel 110 via the hole 122 to destroy the function of the back plate 120. The moisture absorbent 150 disposed adjacent the hole 122 can absorb the moisture around the hole 122 and prevent the moisture from entering the hole 122 of the back plate 120.

The solar module 100 further includes a potting material 170 disposed in the junction box 130 to seal the electronic devices in the junction box 130 and prevent the moisture from entering junction box 130. The potting material 170 can further prevent that the moisture enters the solar cell panel 110 via the back plate 120 from the junction box 130. The solar module 100 further includes a sealant 180 disposed between the junction box 130 and the back plate 120 to seal the hole 122.

The moisture absorbent 150 can be a sheet. The sheet of moisture absorbent 150 can be stuck at the hole 122. The material of the moisture absorbent 150 is selected from a group consisting of zeolite, barium oxide, calcium oxide, and the combination thereof.

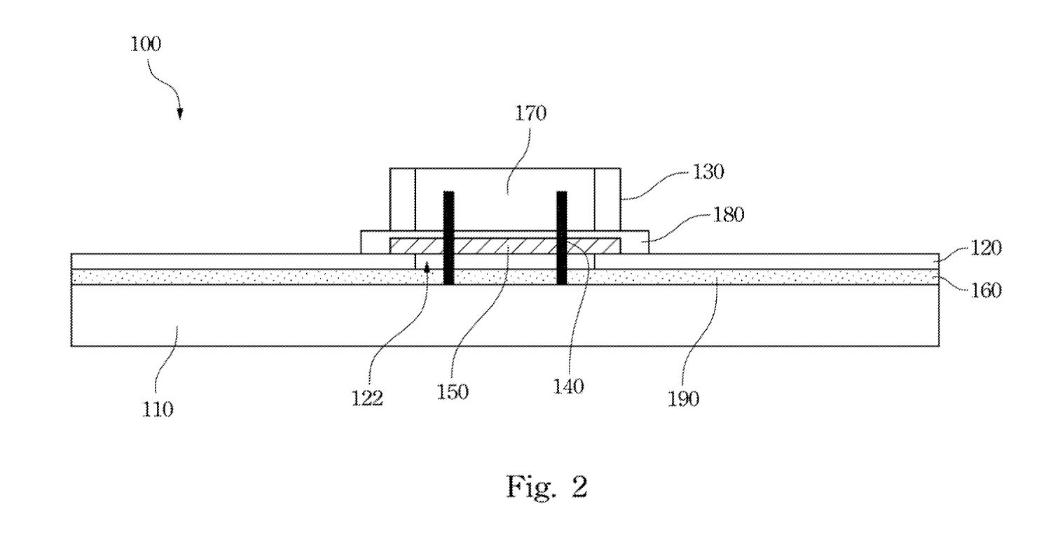

Refer to FIG. 2. FIG. 2 is a cross section diagram of a second embodiment of the invention. The solar module 100 includes the solar cell panel 110, the back plate 120 having the hole 122, the junction box 130, the metallic wires 140 for electrically connecting the junction box 130 and the solar cell of the solar cell panel 110. The metallic wires 140 pass through the hole 122 of the back plate 120 to electrically connect the solar cell panel 110 and the junction box 130. The moisture absorbent 150 is disposed between the solar cell panel 110 and the junction box 130. Specifically, the moisture absorbent 150 can be disposed adjacent to the hole 122 to absorb the moisture and prevent the moisture from entering the hole 122.

The solar module 100 further includes the encapsulant material 160 to encapsulate the back plate 120 and the solar cell panel 110, the potting material 170 disposed in the junction box 130 to seal the electronic devices in the junction box 130, and the sealant 180 disposed between the junction box 130 and the back plate 120 to seal the hole 122.

The solar module 100 further includes a moisture-absorb material 190 blended with the encapsulant material 160. The encapsulant material 160 blended with the moisture-absorb material 190 can absorb the moisture and prevent the moisture from entering the inside of the solar cell panel 110 via the hole and then reacting to the encapsulant material 160. The moisture-absorb material is selected from a group consisting of zeolite, barium oxide, calcium oxide, and the combination thereof.

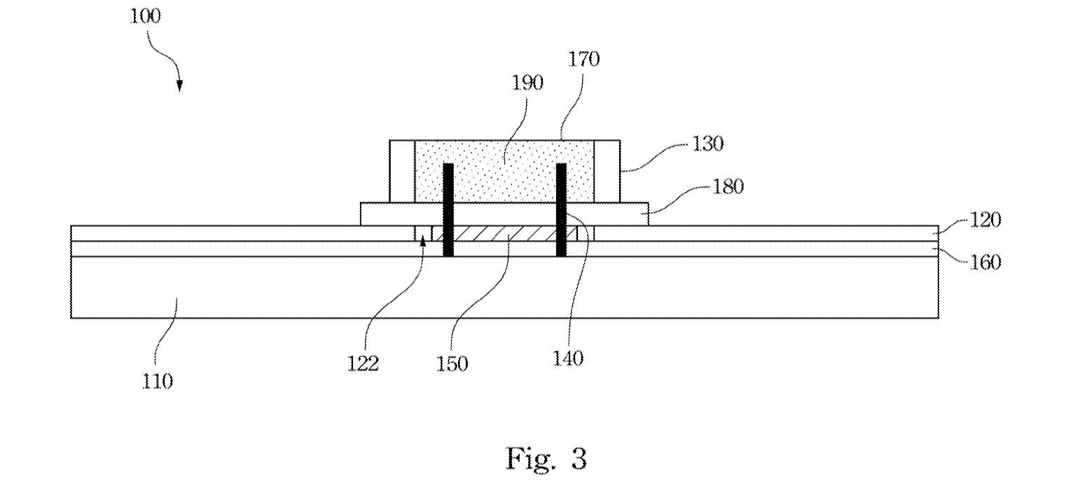

Refer to FIG. 3. FIG. 3 is a cross section diagram of a third embodiment of the invention. The solar module 100 includes the solar cell panel 110, the back plate 120 having the hole 122, the junction box 130, the metallic wires 140 for electrically connecting the junction box 130 and the solar cell panel 110, and the moisture absorbent 150. The metallic wires 140 pass through the hole 122 of the back plate 120 to electrically connect the solar cell panel 110 and the junction box 130. The moisture absorbent 150 is disposed between the solar cell panel 110 and the junction box 130. The moisture absorbent 150 can be disposed adjacent to the hole 122 to absorb the moisture and prevent the moisture from entering the hole 122.

The solar module 100 further includes the encapsulant material 160 to encapsulate the back plate 120 and the solar cell panel 110, the potting material 170 disposed in the junction box 130 to seal the electronic devices in the junction box 130, and the sealant 180 disposed between the junction box 130 and the back plate 120 to seal the hole 122.

The solar module 100 further includes the moisture-absorb material 190. The moisture-absorb material 190 is blended with the potting material 170. The potting material 170 blended with the moisture-absorb material 190 can absorb the moisture and prevent the electronic devices in the junction box from being destroyed by the moisture and prevent the moisture from entering the inside of the solar cell panel 110 via the hole 122. The moisture-absorb material is selected from a group consisting of zeolite, barium oxide, calcium oxide, and the combination thereof.

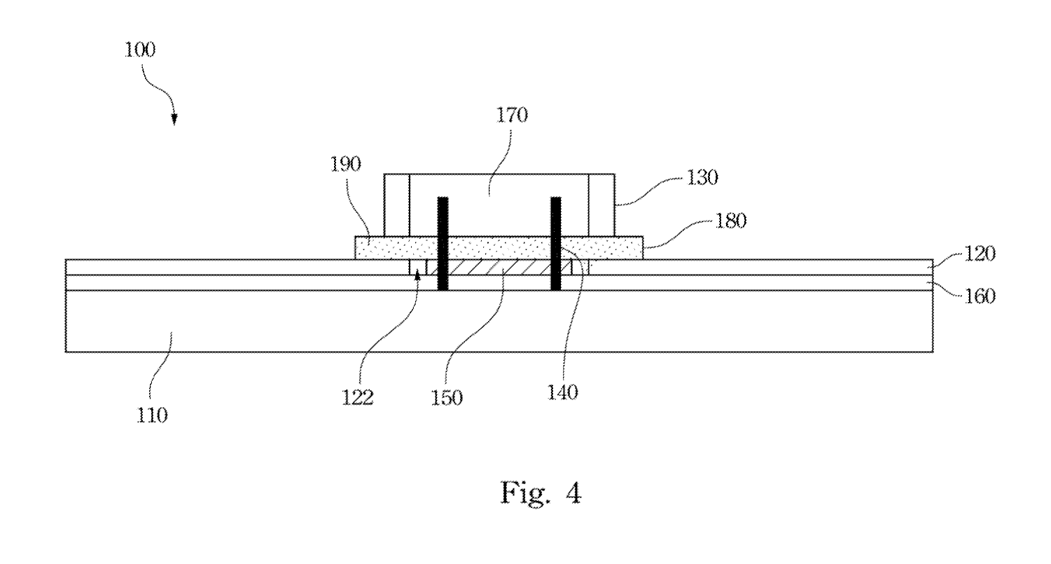

Refer to FIG. 4. FIG. 4 is a cross section diagram of a fourth embodiment of the invention. The solar module 100 includes the solar cell panel 110, the back plate 120 having the hole 122, the junction box 130, the metallic wires 140 for electrically connecting the junction box 130 and the solar cell of the solar cell panel 110, and the moisture absorbent 150. The metallic wires 140 pass through the hole 122 of the back plate 120 to electrically connect the solar cell panel 110 and the junction box 130. The moisture absorbent 150 is disposed between the solar cell panel 110 and the junction box 130. Specifically, the moisture absorbent 150 can be disposed adjacent to the hole 122 to absorb the moisture and prevent the moisture from entering the hole 122.

The solar module 100 further includes the encapsulant material 160 to encapsulate the back plate 120 to the solar cell panel 110, the potting material 170 disposed in the junction box 130 to seal the electronic devices in the junction box 130, and the sealant 180 disposed between the junction box 130 and the back plate 120 to seal the hole 122.

The solar module 100 further includes the moisture-absorb material 190. The moisture-absorb material 190 is blended with the sealant 180. The sealant 180 blended with the moisture-absorb material 190 can seal the hole 122 and absorb the moisture to prevent the moisture from entering the inside of the solar cell panel 110 via the hole 122 and then reacting to the encapsulant material 160. The moisture-absorb material is selected from a group consisting of zeolite, barium oxide, calcium oxide, and the combination thereof.

According to the above embodiments, the solar module of the present invention has the moisture absorbent disposed between the junction box and the solar cell to absorb the moisture around the hole of the back plate. Thus, the solar cell of the solar cell panel 110 and the metallic wires of the solar module 100 around the hole would not rust easily. The solar module may optionally include the moisture-absorb material. The moisture-absorb material can be blended with the encapsulant material, the potting material or the sealant.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar module comprising:
a solar cell panel, comprising a plurality of solar cell;
a back plate, disposed on the solar cell panel, the back plate having a hole;
a junction box, disposed on the back plate;
a plurality of metallic wires passing through the hole for connecting the solar cell panel and the junction box; and
to a moisture absorbent disposed between the junction box and the solar cell panel.

2. The solar module of claim 1, further comprising an encapsulant material for adhering the back plate to the solar cell panel.

3. The solar module of claim 1, further comprising a moisture-absorb material blended with the encapsulant material.

4. The solar module of claim 1, further comprising a potting material disposed in the junction box.

5. The solar module of claim 4, further comprising a moisture-absorb material blended with the potting material.

6. The solar module of claim 1, further comprising a sealant disposed between the junction box and the back plate for sealing the hole.

7. The solar module of claim 6, further comprising a moisture-absorb material blended with the sealant.

8. The solar module of claim 1, wherein a material of the moisture absorbent is selected from a group consisting of zeolite, barium oxide, calcium oxide, and the combination thereof.

9. The solar module of claim 1, wherein the moisture absorbent is a sheet.

10. A solar module comprising:
a solar cell panel, comprising a plurality of solar cell;
a back plate, disposed on the solar cell panel, the back plate having a hole;
a junction box, disposed on the back plate;
a plurality of metallic wires passing through the hole for connecting the solar cell panel and the junction box; and
a moisture absorbent disposed adjacent to the hole.

11. The solar module of claim 10, further comprising an encapsulant material for adhering the back plate to the solar cell panel.

12. The solar module of claim 11, further comprising a moisture-absorb material blended with the encapsulant material.

13. The solar module of claim 10, further comprising a potting material disposed in the junction box.

14. The solar module of claim 13, further comprising a moisture-absorb material blended with the potting material.

15. The solar module of claim 10, further comprising a sealant disposed between the junction box and the back plate for sealing the hole.

16. The solar module of claim 15, further comprising a moisture-absorb material blended with the sealant.

17. The solar module of claim 10, wherein a material of the moisture absorbent is selected from a group consisting of zeolite, barium oxide, calcium oxide, and the combination thereof.

18. The solar module of claim 10, wherein the moisture absorbent is a sheet.
